(19) United States
(12) Patent Application Publication
(10) Pub. No.: US 2008/0087965 A1
(43) Pub. Date: Apr. 17, 2008

(54) STRUCTURE AND METHOD OF FORMING TRANSISTOR DENSITY BASED STRESS LAYERS IN CMOS DEVICES

(75) Inventors: Xiangdong Chen, Poughquag, NY (US); Haining S. Yang, Wappingers Falls, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/548,296

(22) Filed: Oct. 11, 2006

(51) Int. Cl. H01L 21/31; H01L 29/78

(52) U.S. Cl. 257/368; 438/792

(57) ABSTRACT

A method for increasing carrier mobility of transistors included in an semiconductor device includes forming a stress inducing layer over a plurality of transistors, the transistors formed in regions of varying transistor density, wherein the stress inducing layer is formed at a varying thickness depending on the transistor density, such that the stress inducing layer is thicker in regions of increased transistor density and thinner in regions of decreased transistor density.

### BACKGROUND

The present invention relates generally to semiconductor device processing techniques, and, more particularly, to a structure and method of forming transistor density based stress layers in complementary metal oxide semiconductor (CMOS) devices.

Strain engineering techniques have recently been applied to CMOS device manufacturing in order to provide different stresses in P-type MOS (PMOS) devices with respect to N-type MOS (NMOS) devices. For example, a nitride liner of a first type is formed over the PFETs of a CMOS device, while a nitride liner of a second type is formed over the NFETs of the CMOS device. More specifically, it has been discovered that the application of a compressive stress in a PFET channel improves carrier (hole) mobility therein, while the application of a tensile stress in an NFET channel improves carrier (electron) mobility therein, leading to higher on-current and product speed. Thus, the first type nitride liner over the PFET devices is formed in a manner so as to achieve a compressive stress, while the second type nitride liner over the NFET devices is formed in a manner so as to achieve a tensile stress. Conversely, device performance may be reduced when stresses of the opposite type are respectively applied to NFET and PFET devices.

For such CMOS devices employing compressive/tensile liners, the conventional approach has been to form the nitride layer(s) at a given thickness, regardless of the density of the transistor devices in a given location. However, in addition to the thickness of the stress layer, the degree to which carrier mobility is enhanced is also a function of the width of stress layer material adjacent the gate of the device. In other words, devices that are relatively isolated will have a greater width of stress layer material adjacent the gate, because the distance to the gate of the nearest transistor is increased. Moreover, in conventional processing, the stress layer tends to be thinner in nested regions than in isolated regions due to the characteristics of the deposition technique. As a result, the degree of strain applied to the channels of such isolated transistors is relatively greater than the strain applied to the channels of “nested” transistors. This can in turn lead performance disparities between nested and isolated transistors, in terms of carrier mobility enhancement. Accordingly, it would be desirable to be able to implement the formation of stress-inducing liners for CMOS devices in a self-aligned manner that improves performance uniformity with regard to nested and isolated transistor devices.

### SUMMARY

The foregoing discussed drawbacks and deficiencies of the prior art are overcome or alleviated by a method for increasing carrier mobility of transistors included in a semiconductor device. In an exemplary embodiment, the method includes forming a stress inducing layer over a plurality of transistors, the transistors formed in regions of varying transistor density, wherein the stress inducing layer is formed at a varying thickness depending on the transistor density, such that the stress inducing layer is thicker in regions of increased transistor density and thinner in regions of decreased transistor density.

In another embodiment, a method for increasing carrier mobility of transistors included in a semiconductor device includes forming a plurality of MOS (metal oxide semiconductor) transistors on a semiconductor substrate, the transistors being formed in regions of varying transistor density, and forming a stress inducing nitride layer over the plurality of transistors through a high-density plasma (HDP) deposition process. The stress inducing nitride layer is formed at a varying thickness depending on the transistor density, such that the stress inducing layer is thicker in regions of increased transistor density and thinner in regions of decreased transistor density.

In still another embodiment, a semiconductor device structure includes a plurality of MOS (metal oxide semiconductor) transistors formed on a semiconductor substrate, the transistors being formed in regions of varying transistor density, and a stress inducing nitride layer formed over the plurality of transistors. The stress inducing nitride layer has a varying thickness depending on the transistor density, such that the stress inducing layer is thicker in regions of increased transistor density and thinner in regions of decreased transistor density.

In still another embodiment, a semiconductor device structure includes a plurality of MOS (metal oxide semiconductor) transistors formed on a semiconductor substrate, the transistors being formed in regions of varying transistor density, and a stress inducing nitride layer formed over the plurality of transistors. The stress inducing nitride layer produces a varying carrier mobility enhancement for the plurality of transistors as a function of transistor density, such that a higher carrier mobility enhancement is achieved in regions of increased transistor density and with respect to regions of decreased transistor density.

### BRIEF DESCRIPTION OF THE DRAWINGS

Referring to the exemplary drawings wherein like elements are numbered alike in the several Figures:

FIG. 1 is a cross sectional view of a exemplary MOS transistor device having improved carrier mobility as a result of a stress layer that provides an applied mechanical stress to the channel;

FIG. 2 is a block diagram illustrating an exemplary process flow 200 for forming a self-aligned, transistor density based stress layer for improving carrier mobility, in accordance with an embodiment of the invention;

FIG. 3 is a cross sectional view of a semiconductor device having a first region of nested transistors formed therein and a second, isolated region, each including a single nitride layer formed simultaneously thereon through HDP deposition;

FIGS. 4(a) through 4(c) are scanning electron microscopy (SEM) photographs of an HDP formed nitride layer, wherein the thickness thereof varies in accordance with the spacing between adjacent transistors; and

FIG. 5 is a graphical summary of the nitride layer thickness data from FIGS. 4(a) through 4(c).

### DETAILED DESCRIPTION

Disclosed herein is a method of forming transistor density-based stress layers in CMOS devices to improve device uniformity. Briefly stated, the embodiments disclosed herein utilize the effect that the degree of transistor enhancement is proportional to the degree of applied stress, which in turn is proportional to the thickness of the layer creating the applied stress. Accordingly, where transistor devices are denser, the associated stress-inducing layer is formed at a greater thickness than in locations where transistor devices are less dense. That is, the stress layer is formed in a manner such that the thickness of the stress layer at a given location on the semiconductor substrate is a function of the spacing between the transistor devices at that location. More specifically, the thickness of the stress layer increases with decreased transistor spacing (pitch). In an exemplary embodiment, this is carried out through high-density plasma (HDP) deposition of a nitride material, as described hereinafter.

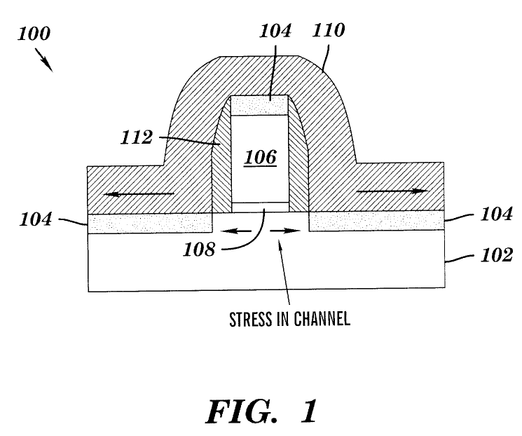

Referring initially to FIG. 1, there is shown a cross sectional view of a exemplary MOS transistor device 100 (e.g., NMOS, PMOS) having improved carrier mobility as a result of a stress layer that provides an applied mechanical stress to the channel (the direction of which depending upon whether the transistor is an NMOS device or a PMOS device). As is shown, the device 100 is formed upon a semiconductor substrate 102 (e.g., silicon, silicon-on-insulator, silicon germanium, etc.). In the particular stage of processing depicted in FIG. 1, salicide (self-aligned silicide) contacts 104 have been formed over the source and drain regions of the device, as well as over the gate electrode 106 formed above the gate insulating layer 108.

As further shown in FIG. 1, a stress inducing nitride layer 110 is formed over the gate structure, sidewall spacers 112, silicided source/drain regions and adjacent areas of the substrate 102. The stress layer 110 is formed prior to deposition of the first interlevel dielectric (ILD) layer thereupon. The stress applied by the layer 110 (indicated by larger arrows) is translated to the channel of the device (indicated by smaller arrows) to improve carrier mobility (and hence Iₒₙ) of the device. If the device 100 is an N-type device, then the nitride layer 110 is of a composition that provides a tensile stress; if a P-type device, then the nitride layer 110 is configured to provide a compressive stress.

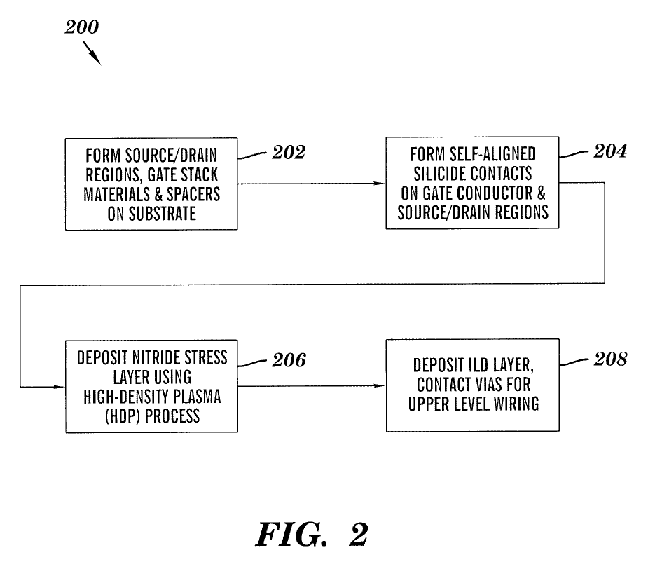

However, as indicated above, the stress layer 110 is conventionally formed in a manner that result in a substantially uniform thickness over transistor devices, regardless of the pitch therebetween. Accordingly, FIG. 2 is a block diagram illustrating an exemplary process flow 200 for forming a self-aligned, transistor density based stress layer for improving carrier mobility, in accordance with an embodiment of the invention. As indicated in block 202, the source/drain regions of the MOS transistors, gate stack materials (e.g., gate insulating layer, polysilicon gate electrode), and sidewall spacers (e.g., silicon nitride) are formed on a substrate in accordance with conventional device processing techniques. As further indicated in block 204, self aligned silicide contacts for the gate conductor, source and drain regions are also formed in accordance with existing silicidation techniques.

Then, as indicated in block 206, a nitride stress layer is formed over the device so as to provide an appropriate type of stress (compressive or tensile) for improving carrier mobility. However, as opposed to conventional stress layer formation techniques, such as chemical vapor deposition (CVD) or physical vapor deposition (PVD), the stress liner is formed using a high-density plasma (HDP) process. The HDP may be carried out, for example, in an HDP chamber configured to provide a plasma power range of about 200 W to about 5000 W, and in an exemplary embodiment, at a high frequency power level of about 400 W and a low frequency power level of about 3600 W.

Additional exemplary HDP process parameters for forming the nitride stress layer include an N₂ flow rate of about 310 sccm, an argon flow rate of about 230 sccm, and a silane (SiH₄) precursor flow rate of about 90 sccm. The substrate is heated at a temperature of about 400° C. during deposition. Further, the heating portion of the HDP process is implemented for about 50 seconds and the deposition portion of the HDP process is implemented for about 15 seconds. Depending upon the particular process conditions, and the density of the transistor devices at a given location of the substrate, a nitride stress layer thickness may be formed at about 20 nm to about 150 nm. Once the nitride stress liner is formed through HDP deposition, additional process may then be performed as known in the art, such as ILD layer formation, via etching and fill, and upper wiring level formation (block 208).

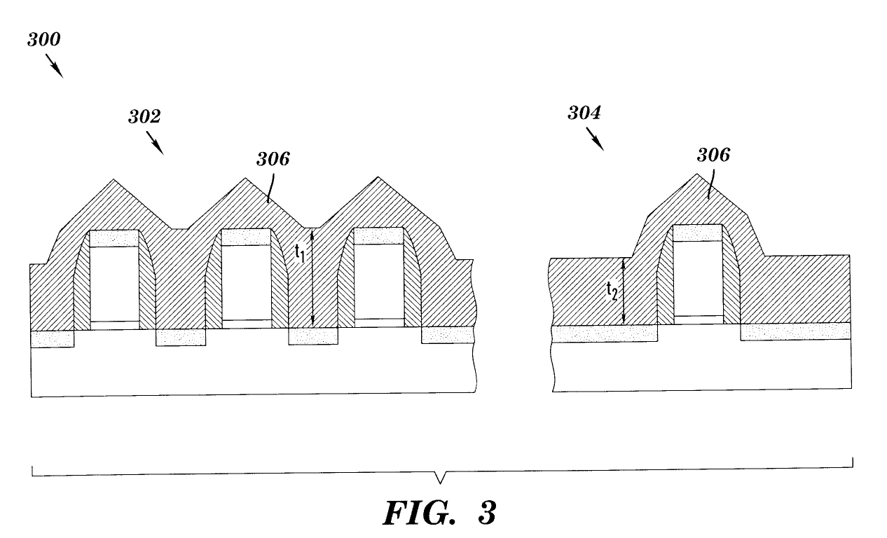

Through the use of HDP deposition, the nitride stress liner is consequently formed at a variable thickness over the surface of the substrate, at an inverse relationship with respect to the distance or pitch between transistor devices. That is, the shorter the pitch, the greater the thickness of the nitride stress layer between adjacent gate structures. FIG. 3 is a cross sectional view of a semiconductor device 300 having a first region 302 of dense “nested” transistors formed therein, and a second, isolated region 304. Both regions 302 and 304 include a single nitride layer 306 formed simultaneously thereon through HDP deposition. However, as can be seen, the thickness (t₁) of the nitride layer 306 between adjacent gate structures in the nested region 302 is greater than the thickness (t₂) of the nitride layer 306 between adjacent gate structures in the isolated region 304.

The additional thickness of the stress layer 306 in the nested region compensates for relative decrease in stress layer width (i.e., gate-to-gate spacing) with respect to devices in the isolated region 304. As a result, the degree of stress applied to the channels of the transistors is more balanced over the entire device.

It has been found that the presently disclosed approach of forming stress layers through HDP deposition is, to date, more particularly suited for compressive stress layers. Thus, in terms of improving carrier mobility, the HDP deposition process is particularly desirable for PMOS devices. However, it should be appreciated that subsequent improvements in HDP deposition techniques may make the process equally desirable for forming tensile nitride layers that improve electron mobility in NMOS devices.

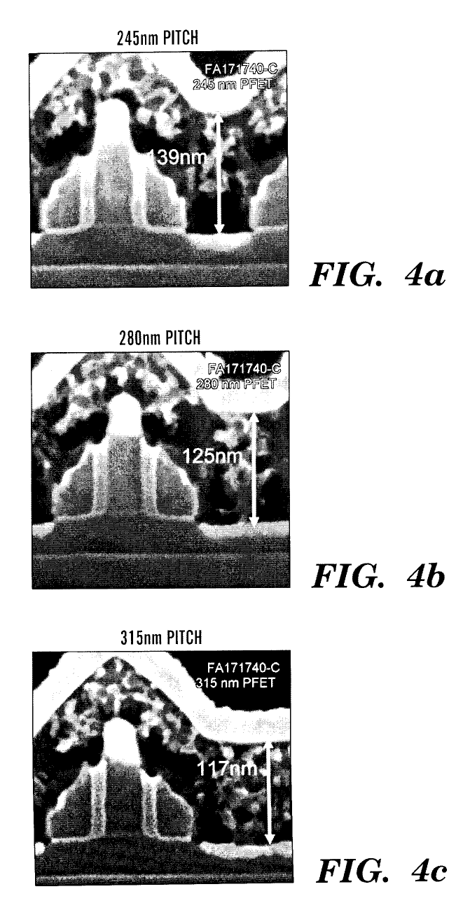

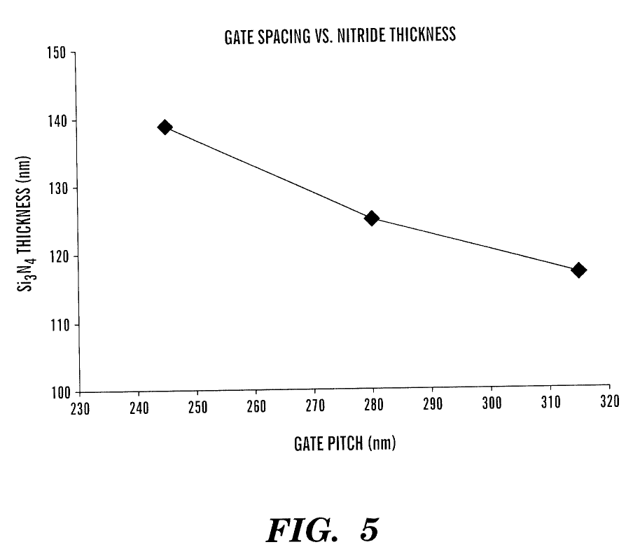

Finally, FIGS. 4 and 5 illustrate nitride thickness results for an HDP deposited, compressive nitride layer formed over a plurality of PFET devices in accordance with the techniques described above. Specifically, FIGS. 4(a) through 4(c) are scanning electron microscopy (SEM) photographs of the HDP formed nitride layer, wherein the thickness thereof varies in accordance with the spacing between adjacent transistors. For example, in a nested region of the device where the pitch between adjacent PFETs is about 245 nm, the resulting thickness of the nitride layer is about 139 nm, as shown in FIG. 4(a). As the pitch increases to about 280 nm in FIG. 4(b), the resulting thickness of the nitride layer is decreased to about 125 nm. As then shown in FIG. 4(c), the thickness of the nitride layer is further decreased down to about 117 nm at a pitch of about 315 nm. The data is summarized in graphical form in FIG. 5. Although not shown in the figures, the thickness of the nitride layer in the isolated regions of the device was about 107 nm.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for increasing carrier mobility of transistors included in a semiconductor device, the method comprising:
forming a stress inducing layer over a plurality of transistors, the transistors formed in regions of varying transistor density;
wherein the stress inducing layer is formed at a varying thickness depending on the transistor density, such that the stress inducing layer is thicker in regions of increased transistor density and thinner in regions of decreased transistor density.

2. The method of claim 1, wherein the stress inducing layer is formed through a high-density plasma (HDP) deposition process.

3. The method of claim 2, wherein the stress inducing layer comprises a nitride material.

4. The method of claim 3, wherein the stress inducing layer is a compressive nitride material and the plurality of transistors comprise P-type devices.

5. The method of claim 3, wherein the stress inducing layer is a tensile nitride material and the plurality of transistors comprise N-type devices.

6. The method of claim 2, wherein the HDP deposition process is implemented using an N₂ flow rate of about 310 sccm, an argon flow rate of about 230 sccm, and a silane (SiH₄) precursor flow rate of about 90 sccm.

7. The method of claim 2, wherein the substrate is heated at a temperature of about 400° C. during deposition.

8. The method of claim 2, wherein a heating portion of the HDP process is implemented for about 50 seconds and a deposition portion of the HDP process is implemented for about 15 seconds.

9. A method for increasing carrier mobility of transistors included in an semiconductor device, the method comprising:
forming a plurality of MOS (metal oxide semiconductor) transistors on a semiconductor substrate, the transistors being formed in regions of varying transistor density; and
forming a stress inducing nitride layer over the plurality of transistors through a high-density plasma (HDP) deposition process;
wherein the stress inducing nitride layer is formed at a varying thickness depending on the transistor density, such that the stress inducing layer is thicker in regions of increased transistor density and thinner in regions of decreased transistor density.

10. The method of claim 9, wherein the stress inducing layer is a compressive nitride material and the plurality of transistors comprise PMOS devices.

11. The method of claim 9, wherein the stress inducing layer is a tensile nitride material and the plurality of transistors comprise NMOS devices.

12. The method of claim 9, wherein the HDP deposition process is implemented using an N₂ flow rate of about 310 sccm, an argon flow rate of about 230 sccm, and a silane (SiH₄) precursor flow rate of about 90 sccm.

13. The method of claim 9, wherein the substrate is heated at a temperature of about 400° C. during deposition.

14. The method of claim 9, wherein a heating portion of the HDP process is implemented for about 50 seconds and a deposition portion of the HDP process is implemented for about 15 seconds.

15. A semiconductor device structure, comprising:
a plurality of MOS (metal oxide semiconductor) transistors formed on a semiconductor substrate, the transistors being formed in regions of varying transistor density; and
a stress inducing nitride layer formed over the plurality of transistors;
wherein the stress inducing nitride layer has a varying thickness depending on the transistor density, such that the stress inducing layer is thicker in regions of increased transistor density and thinner in regions of decreased transistor density.

16. The structure of claim 15, wherein the stress inducing layer is a compressive nitride material and the plurality of transistors comprise PMOS devices.

17. The structure of claim 15, wherein the stress inducing layer is a tensile nitride material and the plurality of transistors comprise NMOS devices.

18. A semiconductor device structure, comprising:
a plurality of MOS (metal oxide semiconductor) transistors formed on a semiconductor substrate, the transistors being formed in regions of varying transistor density; and
a stress inducing nitride layer formed over the plurality of transistors;
wherein the stress inducing nitride layer produces a varying carrier mobility enhancement for the plurality of transistors as a function of transistor density, such that a higher carrier mobility enhancement is achieved in regions of increased transistor density and with respect to regions of decreased transistor density.
